(19) United States
(12) Patent Application Publication
(10) Pub. No.: US 2021/0358348 A1
(43) Pub. Date: Nov. 18, 2021

(54) COLORED LIGHT EMITTING CELL FOR IMAGING UNIT WITH PRIMARY COLOR SELECTION THANKS TO OSCILLATING COMPONENT

(71) Applicant: OSRAM Opto Semiconductors GmbH, Regensburg (DE)

(72) Inventors: Gunnar PETERSEN, Regensburg (DE); Daniel RICHTER, Bad Abbach (DE); Michael FOERSTER, Regensburg (DE); Nicole BERNER, Walderbach (DE); Konrad WAGNER, Regensburg (DE)

(21) Appl. No.: 17/286,361

(22) PCT Filed: Oct. 15, 2019
(86) PCT No.: PCT/EP2019/077985

§ 371 Date: Apr. 16, 2021

(30) Foreign Application Priority Data
Oct. 19, 2018 (DE) 10 2018 126 113.6

(51) Int. Cl. G09F 9/37; G09F 9/33; H01L 33/50; H01L 25/075

(52) U.S. Cl. CPC G09F 9/37; H01L 25/0753; H01L 33/502; G09F 9/33

(57) ABSTRACT

A light emitting cell for use as a pixel, the light emitting cell being configured to generate the three primary colors and to form different color tones therewith, comprising: a light emitting front surface, a rear surface, and a substrate arranged between the front and rear surface; a light source carried by the substrate; three luminous sections, comprising a blue luminous section, a light converting red luminous section, and a light converting green luminous section; and a primary color selection device capable of performing a repetitive movement at a certain frequency so that, during this movement, one of the luminous sections is alternately selected as a potential light emitting section, characterized in that the primary color selection device is a single mechanical component that serves to select all three luminous sections.

### RELATED APPLICATIONS

The present application claims priority to German patent application DE 10 2018 126 113.6, filed Oct. 19, 2018, the full content of which is hereby incorporated by reference into the present application.

### FIELD OF THE INVENTION

The present invention is in the field of imaging units, such as color displays. In particular, it relates to the structure of the individual pixels of such an imaging unit.

### BACKGROUND OF THE INVENTION

A light emitting cell for use as a pixel in an imaging unit, such as a color screen, is known from document US 2014/0036536 A1. This is shown in FIG. 9 thereof. This known light emitting cell is configured to generate the three primary colors red, green, and blue, and to form and output different color tones with the three generated primary colors. The light emitting cell comprises the following:
A light emitting front surface, a rear surface opposite the front surface, and a substrate arranged between the front and rear surface;
A light source for emitting light carried by the substrate;
Three spatially separated luminous sections, having a first blue luminous section, a second red luminous section that converts light from the light source to the primary color red, and a third green luminous section that converts light from the light source to the primary color green, the three luminous sections being located between the light source and the front surface; and
A primary color selection device which is arranged between the front surface and the light source, wherein the primary color selection device can perform a repetitive movement with a certain frequency so that one of the luminous sections is alternately selected as a potential light emitting section during this movement. In this light emitting cell, a white backlight, three separate bezels, and three quantum dots are used to generate different color tones.

However, this light emitting cell has a complex and therefore costly as well as space-consuming structure.

### SUMMARY OF THE INVENTION

It is therefore an object of the present invention to further develop the light emitting cell of the type defined at the beginning in such a way that its structure is simplified and reduced in size.

According to the invention, this object is solved in that the primary color selection device is designed as a single mechanical component that serves to select all three luminous sections.

By providing a single mechanical component to select all three luminous sections, a particularly compact light emitting cell is obtained that also has a simple structure. In contrast, the aforementioned prior art requires three separate bezels that must be coordinated and require space.

Preferably, the light source can consist of a blue LED for generating the blue primary color. By using a blue LED, one already has a primary color. Furthermore, the blue light can be easily converted into the two other primary colors red and green.

In this case, the blue luminous section can be transparent to the light of the LED in the blue primary color, in which case the blue luminous section is preferably a recess. The blue luminous section can therefore be implemented particularly easily.

In one embodiment, the single mechanical component can be vibrated such that for alternate selection of the light sections a movement is performed substantially perpendicular to the main light output direction of the light emitting cell. This con-tributes to the compactness of the light emitting cell.

The single mechanical component can be a movable layer, in particular a silicone layer. This makes it easier to manufacture the component.

In this case, the luminous sections can be formed in the movable layer.

The single mechanical component can also alternatively be a bezel. A bezel can be moved in a controlled and safe manner.

Thereby the luminous sections can be formed in the bezel. This reduces the overall height of the light emitting cell.

Alternatively, the luminous sections can be arranged in the form of a common layer between the light source and the bezel. This simplifies the manufacture of the bezel.

The movement of the mechanical component can be a translatory back-and-forth movement. Such a movement can be easily provided, e.g. by means of piezoelectric elements.

In one variant, the luminous sections can be formed substantially cuboidal. Such a form is particularly practical to manufacture.

The bezel can be set into a rotating movement for the purpose of alternate selection of the luminous sections, preferably by oscillation along two mutually perpendicular directions. A rotating bezel does not take up any additional space in its rotary movement.

In this case, the luminous sections can have essentially the form of cake pieces. This form is best suited for the rotating movement.

The present invention also comprises a light emitting matrix comprising a plurality of preferred light emitting cells, as further defined above, arranged in one or more rows, wherein the movable layers of the individual light emitting cells are combined to form a movable total layer.

The present invention likewise comprises a color display screen comprising a plurality of light emitting cells defined above or at least one light emitting matrix defined in the previous paragraph.

### SHORT DESCRIPTION OF THE FIGURES

Preferred embodiments of the invention are now described with reference to the drawings, wherein:

FIG. 1a shows a first variant of a light emitting cell according to the invention in side view;

FIG. 1b is a top view of a bezel of the light emitting cell of FIG. 1a;

FIG. 1c shows two curves illustrating the functionality of the light emitting cell of FIG. 1a;

FIG. 2 shows a second variant of a light emitting cell according to the invention;

FIG. 3 illustrates a third variant of a light emitting cell according to the invention; and

FIG. 4 shows a fourth variant of a light emitting cell according to the invention.

### DETAILED DESCRIPTION OF PREFERRED EMBODIMENTS

In the following description, exemplary embodiments of the present invention are described with reference to the drawings. The drawings are not necessarily to scale, but are merely intended to illustrate the respective features schematically.

It should be noted that the features and components described below may each be combined with one another, regardless of whether they have been described in connection with a single embodiment. The combination of features in the respective embodiments serves only to illustrate the basic construction and operation of the claimed device.

The four different embodiments shown in the figures each involve a light emitting cell. Such light emitting cells are intended to perform the function of a pixel in an imaging unit. The imaging unit may be, for example, a color screen. Color screens are used as parts of computer systems, televisions, cell phones or other electronic devices to display images and videos or the like. A large number of light emitting cells are thereby arranged in rows and columns to form a light emitting matrix.

The light emitting cells according to the invention shown in the figures are colored light emitting cells. This means that they are configured to generate the three primary colors red, green and blue and to form and output different color tones with the three primary colors generated.

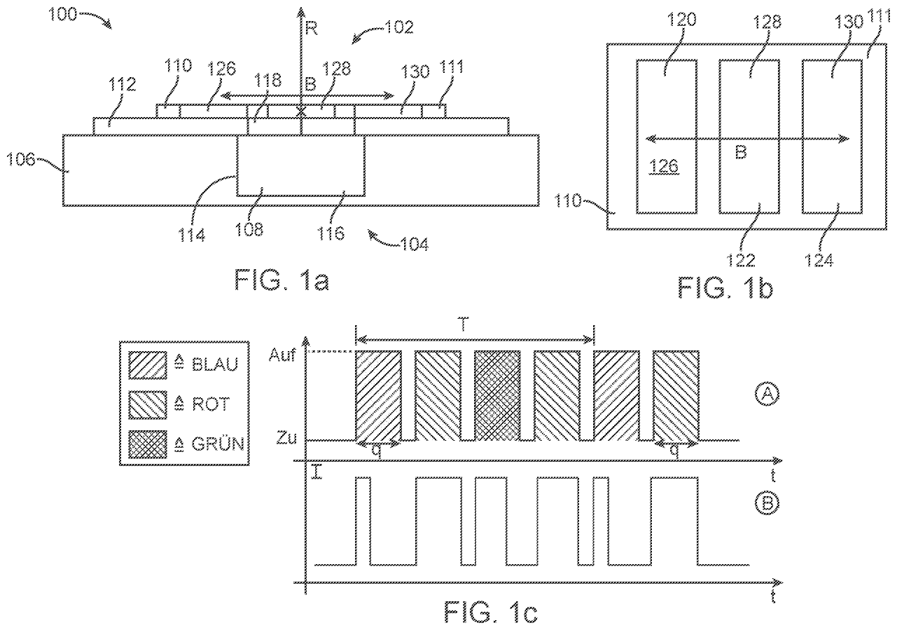

With reference to FIG. 1a, a side view of a first embodiment 100 of a light emitting cell according to the invention is seen.

This light emitting cell 100 has a light emitting front surface 102 and a rear surface 104 opposite to the front surface. The light emitting cell 100 has a main light emitting direction R. The light generated by the light emitting cell 100 is mainly emitted in the direction R.

The light emitting cell 100 comprises the following components: a substrate 106, a light source 108 carried by the substrate 106, a primary color selection device 110, and a carrier 112 carrying the primary color selection device 110.

The substrate 106 carries all of the other components 108, 110, and 112. The substrate 106 can thus also be referred to as the base. One side of the substrate 106 forms the rear surface 104 of the light emitting cell 100. The substrate 106 is preferably made of a material typically used to make printed circuit boards (PCBs). To provide a flat/planar surface for mounting the carrier 112 on the substrate 106, a planarization layer (not shown) of, for example, epoxy resin or silicone can be provided on the front surface of the substrate 106 and over the light source 108.

The substrate 106 houses the light source 108. More specifically, the light source 108 is seated in a recess 114 of the substrate 106. The light source 108 comprises a housing 116. As shown in FIG. 1a, the housing 116 can be flush with the substrate 106. In other words, the housing 116 of the light source 108 is neither recessed into the interior of the substrate 106, nor does it protrude the substrate 106.

The light source 108 preferably comprises a light emitting diode, or LED. The light source 108 then preferably presents itself as an LED chip. In the present embodiment, the LED chip 108 comprises a blue LED for generating the blue primary color.

On the substrate 106 and above the blue LED chip 108 is the carrier 112. The carrier 112 is formed in the form of a layer. Above the LED chip 108, the carrier layer 112 has a light outlet 118, which is preferably a hole 118 formed approximately centrally in the carrier layer 112. The blue light generated by the LED chip 108 can pass through the carrier layer 112 via the hole 118.

The primary color selection device 110 is designed here as a bezel. A top view of the bezel 110 is shown in FIG. 1b. The bezel 110 is carried by the carrier layer 112.

It can be seen that the primary color selection device 110 or bezel 110 is a single mechanical component. In other words, the primary color selection device 110 forms a self-contained unit. Thus, it is not an assembly comprising multiple discrete elements. Rather, this single mechanical component 110 has a self-contained base body 111. This base body 111 has a fixed extent and fixed dimensions. The dimensions and extent of the base body 111 determine the dimensions and extent of the primary color selection device 110. Thus, the primary color selection device 110 has a single materially cohesive base body 111.

The bezel 110 has a substantially rectangular form when viewed from above. The bezel 110 is provided with three slots 120, 122 and 124. Each of these slots 120, 122 and 124 has a substantially rectangular form. The slots 120, 122 and 124 preferably have the same orientation. In the present example, they are arranged in a row one behind the other in the bezel 110. In the slots 120, 122 and 124 there are three spatially separated luminous sections 126, 128 and 130. There is a first blue luminous section 126, a second red luminous section 128 and a third green luminous section 130. The red luminous section 128 is configured to convert blue light emitted by the blue LED chip 108 into the primary color red. The green luminous section 130 is configured to convert the light emitted from the blue LED chip 108 into the primary color green.

Due to their arrangement within the bezel 110, the three luminous sections 126, 128, and 130 are located between the blue LED chip 108 and the front surface 102 of the light emitting cell 100. In the present example, the luminous sections 126, 128, and 130 comprise a substantially cuboidal form.

In the present case, the red luminous section 128 is located in the center of the bezel 110. It is flanked on one side by the blue luminous section 126 and on the other side by the green luminous section 130. The three luminous sections 126, 128, 130 could of course also be realized in a different order in the bezel 110. In this embodiment, there is in any case a central luminous section and two lateral luminous sections.

The luminous sections 128 and 130 are both designed as light conversion layers. The blue luminous section 126, on the other hand, is simply transparent to the light of the LED chip 108 in the blue primary color. Thus, no light conversion takes place in the blue luminous section 126. Preferably, the blue luminous section 126 is a hole or recess formed in the bezel 110.

The red luminous section 128 and the green luminous section 130 can be silicone layers in which light conversion agents such as phosphors or so-called quantum dots are distributed. In the red luminous section 128, light conversion agents are embedded which are suitable for converting the blue light emitted by the blue LED chip 108 into red light. The light conversion agents absorb the blue light, are excited by it, and then fall back to their previous state by emitting red light. In FIG. 1a, the conversion of the blue light is indicated by a cross in the red light conversion layer 128.

The same applies to the green luminous section 130, where the phosphors or quantum dots are selected to convert the blue light into green light.

The bezel 110 is mounted on the carrier layer 112 in such a way that it can perform a repetitive translational back-and-forth motion at a certain frequency relative to the carrier layer 112. This is indicated by the double arrow B in FIGS. 1a and 1b. Here, the movement B is substantially perpendicular to the main light output direction R of the light emitting cell 100.

The bezel 110 and the carrier layer 112 are sized in relation to each other such that when the movement B through the bezel 110 is executed, never more than one of the three luminous sections 126, 128 and 130 is completely above the light outlet 118 in the carrier layer 112. This is achieved by the size of the light outlet 118 in the carrier layer 112 being between one and twice the size of the luminous sections 126, 128 and 130. Preferably, the luminous sections 126, 128 and 130 have the same size. In this case, the bezel 110 always covers the light outlet 118. The bezel 110 is preferably formed as a platelet.

The Functionality of the light emitting cell 100 as shown in FIG. 1 will now be described. Reference is also made to the curves shown in FIG. 1c.

By adjusting the control of the oscillating movement B of the bezel 110 and a suitable current supply to the LED chip 108, the primary colors blue, red and green can be mixed differently with the light emitting cell 100 and thus any color tones can be generated. In doing so, the bezel 110 oscillates about a central position shown in FIG. 1a. In the central position, the red luminous section 128 is located above the light outlet 118 of the carrier layer 112.

During oscillation, the bezel 110 experiences a maximum deflection in a direction in which the blue luminous section 126 is completely over the light outlet 118 of the carrier layer 112, and a maximum deflection in the opposite direction in which the green luminous section 130 is completely over the light outlet 118 of the carrier layer 112.

With reference to FIG. 1c, an example of a possible control of the oscillation of the bezel 110 and a corresponding control of the current supply of the blue LED chip 108 is explained.

As can be seen from the curve marked with the capital letter A, the bezel 110 performs an oscillation with a period T (i.e. with a frequency F=1/T). During a period T, the blue luminous section 126, the red luminous section 128, the green luminous section 130, and again the red luminous section 128 are successively located above the light outlet 118 of the carrier layer 112. This process is repeated again and again. The rectangular shape of the curve A makes it clear that each of the three luminous sections 126, 128, 130 dwells over the LED chip 108 for an equal period of time q and then another luminous section is brought into overlap with the LED chip 108 by a jerky dis-placement of the bezel 110. Thus, each of the three luminous sections 126, 128 and 130 is regularly located above the LED chip 108.

The generation of a specific color tone is now achieved by supplying power to the LED chip 108 only within specific intervals in which the luminous section 126, 128, 130 necessary for the color tone is located above the LED chip 108. For example, if it is desired to generate a pure blue color tone, the LED chip 108 will be supplied with power only during the intervals when the blue luminous section 126 is located above the light outlet 118. At all other times, the LED chip 108 remains de-energized and thus does not generate light.

The generation of a color mixture is illustrated with the curve in FIG. 1c, denoted by the capital letter B. By energizing the LED chip 108 according to curve B, a color mixture of red, green and blue is obtained. In this color mixture, some green and some blue are added to the red. In fact, the blue LED chip 108 is always supplied with power over the entire interval in which the red light section 128 is above the LED chip 108. However, the LED chip 108 is only powered for slightly more than half of the interval in which the green luminous section 130 is above the LED chip 108. During the intervals in which the blue luminous section 126 is above the blue LED chip 108, the LED chip 108 is energized for a small fraction of the interval.

It could also be said that a luminous section 126, 128, 130 is selected as a potential light emitting section by the movement B of the primary color selection device. The selected luminous section is only potentially a light emitting section, since light emission by it occurs only when power is supplied to the LED chip 108 at the moment of selection. In this first embodiment, the selection is performed by moving the luminous section into position above the LED chip 108. It is found that by means of the one single bezel 110, all three luminous sections 126, 128, 130 can be selected for potential light emission.

Of course, other ways of controlling the bezel 110 and the LED chip 108 are conceivable.

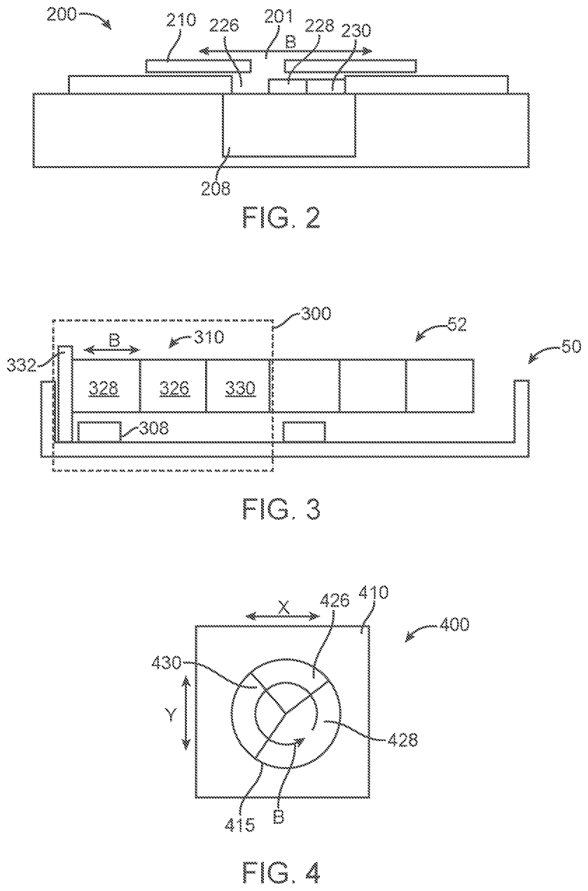

With reference to FIGS. 2-4, three variants of light emitting cells according to the invention are now described. Only the differences from the light emitting cell 100 of FIG. 1 will be discussed. For the components which are the same, what has been said above with respect to FIG. 1 applies.

In the variant 200 shown in FIG. 2, the main difference is that the bezel 210 is designed simpler. This only has a central slot 201. In this variant, the light sections 226, 228 and 230 are arranged in the form of a common layer between the LED chip 208 and the bezel 210. This common layer sits on the light emitting side of the LED chip 208. In the present example, the blue luminous section 226 consists of a free space through which the blue light from the LED chip 208 passes to the bezel 210. The red luminous section 228 and the green luminous section 230 consist, for example, of silicone layers mixed with appropriate light conversion agents. These are applied to the light emitting surface of the LED chip 108. The red luminous section 228 is located centrally on the LED chip 208. The green luminous section 230 is located on the periphery of the same. Of course, the three luminous sections 226, 228 and 230 can also be arranged in other ways on the LED chip 208.

The bezel slot 201 is substantially the same size as one of the luminous sections 226, 228, and 230. The luminous sections 226, 228, and 230 having the same size.

The oscillation of the bezel 210 and the power supply of the LED chip 208 can be performed according to the curves A and B of FIG. 1c. In the light emitting cell 200 of FIG. 2, light conversion occurs before the light passes the bezel. In contrast, the light conversion in the light emitting cell 100 of FIG. 1a takes place when the light passes the bezel.

With reference to FIG. 3, a third embodiment 300 of a light emitting cell according to the invention is now described. In this light emitting cell 300, the primary color selection device 310 is designed as a movable layer. This layer 310 consists of a homogeneous carrier material to which light conversion agents have been added in partial regions. It can, for example, be a silicone layer. This silicone layer 310 sits above the light output opening of the LED chip 308. Each luminous section 326, 328 and 330 forms a partial region of the layer 310. Each partial region preferably has the same size. Each partial region 326, 328, 330 is at least of the size of the LED chip 308. This ensures that when a partial region is placed in position over the LED chip 308, it intercepts substantially all of the blue light emitted by the LED chip 308. Unlike the red luminous section 328 and the green luminous section 330, which are made of material mixed with light conversion agents, the blue luminous section 326 is made of the same material but without the addition of light conversion agents. This base material must, of course, be light transmissive. The three luminous sections 326, 328, 330 are arranged one behind the other in a row. In contrast to the first two variants, here the blue luminous section 326 is located in the center and the red luminous section 328 and the green luminous section 330 are located at the side of the primary color selection device 310. The luminous sections can, of course, also be lined up differently.

The light emitting cell 300 also has an actuator 332. This can be used to cause the movable layer 310 to vibrate in such a way that one of its luminous sections is alternately brought into position above the LED chip 108. The actuator 332 can, for example, be a piezoelectric element.

FIG. 3 also shows a light emitting matrix 50 according to the invention, comprising a plurality of light emitting cells 300 arranged in one or more rows. In this case, the movable layers 310 of the light emitting cells 300 are combined to form a movable total layer 52. In such a light emitting matrix 50, the total layer 52 is centrally vibrated by an actuator 332. This total layer 52 then moves in a back and forth motion over all LED chips 308 of the light emitting matrix 50. This light emitting matrix 50 according to the invention has the advantage that only a single layer 52 needs to be oscillated to form the color tones of several pixels. Thus, one does not need a separate actuator and a separate movable layer for each individual pixel. This means that components can be saved.

FIG. 4 shows a fourth embodiment 400 of a light emitting cell according to the invention. The light emitting cell 400 is shown here in a top view, in which only its bezel 410 is visible. The bezel 410 comprises preferably a square form. At the center of the bezel 410 is a circular region 415. The circular region 415 is divided into three sectors of a circle. The three circular sectors correspond to three luminous sections 426, 428 and 430. Thus, here the luminous sections are essentially cake pieces. In the present example, the red luminous section 428 is larger than the green luminous section 430, and the latter is in turn larger than the blue luminous section 426. For alternate selection of the luminous sections, the bezel 410 can be set into a rotational motion, as indicated by the arrow B. Preferably, this can be done by oscillating the bezel 410 in two directions X and Y perpendicular to each other.

In summary, the light emitting cells according to the invention offer the following advantages in particular:
the LED of a light emitting cell only lights up when it is really needed. This increases energy efficiency compared to known backlighting solutions with a white LED;
each light emitting cell requires only one LED. Other state-of-the-art light emitting cells use three LEDs, which is significantly more expensive;
with the use of bezels according to the invention, a high contrast ratio can also be achieved between the individual colors;
the emission center of the differentiated colors is the same for the three primary colors. This results in a very well perceived color mixture.

The light emitting cells according to the invention could also be called Micro Electro Mechanical Systems or MEMS.

### LIST OF REFERENCE SIGNS

50 LIGHT EMITTING MATRIX
52 MOVABLE TOTAL LAYER
100, 200, 300, 400 LIGHT EMITTING CELL
102 FRONT SURFACE
104 REAR SURFACE
106 SUBSTRATE
108, 208, 308 LED CHIP
110, 210, 310, 410 PRIMARY COLOR SELECTION DEVICE
112 CARRIER LAYER
114 RECESS
116 HOUSING
118 LIGHT OUTLET
120, 122, 124 SLOT
126, 128, 130 LUMINOUS SECTIONS
226, 228, 230 LUMINOUS SECTIONS
326, 328, 330 LUMINOUS SECTIONS
426, 428, 430 LUMINOUS SECTIONS
111 BASE BODY
201 SLOT
332 ACTUATOR
415 CIRCULAR REGION
B DIRECTION OF MOVEMENT
R MAIN LIGHT OUTPUT DIRECTION
T PERIOD
q TIME INTERVAL
I CURRENT
X, Y OSCILLATION DIRECTION

1. A light emitting cell for use as a pixel in an imaging unit, such as a color display screen, the light emitting cell being configured to generate the three primary colors red, green and blue and to form and output different color tones with the three generated primary colors, the light emitting cell comprising:
a light emitting front surface, a rear surface opposite the front surface, and a substrate arranged between the front and rear surface;
a light source for emitting light carried by the substrate;
three spatially separated luminous sections, comprising a first blue luminous section, a second red luminous section that converts light from the light source to the primary color red, and a third green luminous section that converts light from the light source to the primary color green, the three luminous sections being located between the light source and the front surface; and
a primary color selection device arranged between the front surface and the light source, wherein the primary color selection device is capable of performing a repetitive movement at a certain frequency such that during this movement one of the luminous sections is alternately selected as a potential light emitting section,
characterized in that the primary color selection device is a single mechanical component that serves to select all three luminous sections.

2. The light emitting cell according to claim 1,
characterized in that the light source comprises a blue LED for generating the blue primary color.

3. The light emitting cell according to claim 2,
characterized in that the blue luminous section is transmissive to the light of the LED in the blue primary color, the blue luminous section preferably being a recess.

4. The light emitting cell according to claim 1,
characterized in that the single mechanical component can be vibrated such that for alternate selection of the light sections a movement is performed substantially perpendicular to the main light output direction of the light emitting cell.

5. The light emitting cell according to claim 1,
characterized in that the single mechanical component is a movable layer, in particular a silicone layer.

6. The light emitting cell according to claim 5,
characterized in that the luminous sections are formed in the movable layer.

7. The light emitting cell according to claim 1,
characterized in that the single mechanical component is a bezel.

8. The light emitting cell according to claim 7,
characterized in that the luminous sections are formed in the bezel.

9. The light emitting cell according to claim 7,
characterized in that the luminous sections are arranged in the form of a common layer between the light source and the bezel.

10. The light emitting cell according claim 4,
characterized in that the single mechanical component is a movable layer, in particular a silicone layer, and the movement of the mechanical component is a translational reciprocating movement.

11. The light emitting cell according to claim 1,
characterized in that the luminous sections are formed substantially cuboidal.

12. The light emitting cell according to claim 7,
characterized in that the bezel can be set in a rotational movement for the purpose of alternate selection of the luminous sections, preferably by oscillation along two mutually perpendicular directions.

13. The light emitting cell according to claim 12,
characterized in that the luminous sections are substantially in the form of cake pieces.

14. A light emitting matrix comprising a plurality of light emitting cells according to claim 5 arranged in one or more rows, wherein the movable layers of the individual light emitting cells are combined to form a movable total layer.

15. A color display screen comprising a plurality of light emitting cells according to claim 1.

16. A color display screen comprising at least one light emitting matrix according to claim 14.
